(19) United States
(12) Patent Application Publication
(10) Pub. No.: US 2025/0357939 A1
(43) Pub. Date: Nov. 20, 2025

(54) ATOMIC OSCILLATOR

(71) Applicant: NEC Corporation, Tokyo (JP)

(72) Inventor: Takahiro FUJISAKU, Tokyo (JP)

(73) Assignee: NEC Corporation, Tokyo (JP)

(21) Appl. No.: 19/189,432

(22) Filed: Apr. 25, 2025

(30) Foreign Application Priority Data
May 16, 2024 (JP) 2024-079927

(51) Int. Cl. H03L 7/26; G04F 5/14; H03L 1/00; H03L 1/02

(52) U.S. Cl. CPC H03L 7/26; H03L 1/00; H03L 1/022; G04F 5/145

(57) ABSTRACT

An atomic oscillator of the present disclosure includes: a gas cell in which alkali metal atoms are encapsulated; a light generator that irradiates the gas cell with irradiation light having at least two different frequency components; a light detector that detects transmitted light transmitted through the gas cell; and a controller that determines a resonance frequency based on a light amount of the transmitted light of the gas cell and controls an oscillation frequency by an oscillator based on the determined resonance frequency, and includes an agent that performs reinforcement learning so as to output an action controlling an environmental state of the atomic oscillator in accordance with the acquired environmental state, by using a reward corresponding to a difference between a preset reference frequency and the oscillation frequency.

### INCORPORATION BY REFERENCE

This application is based upon and claims the benefit of priority from Japanese patent application No. 2024-079927, filed on May 16, 2024, the disclosure of which is incorporated herein in its entirety by reference.

### TECHNICAL FIELD

The present invention relates to an atomic oscillator.

### BACKGROUND ART

An atomic oscillator is a device that measures the exact time based on the natural frequency of an atom. In a small atomic clock, the natural frequency of an atom is measured mainly using Coherent Population Trapping (CPT), which is a quantum interference effect occurring when an alkali metal atomic gas is irradiated with excitation light of two frequencies, as the oscillation principle of an atomic oscillator. In CPT, when the difference between the two excitation light frequencies matches the transition frequency between the alkali metal ground levels, the absorption of the excitation light does not occur and the amount of transmitted light increases. In the atomic oscillator with CPT as the operation principle, the difference between the two excitation light frequencies is swept and the resonance frequency, which is the difference between the frequencies at which the amount of transmission light reaches the maximum, is set as the natural frequency of the atom. One of the performance indicators of the atomic oscillator is whether the resonance frequency, which is the natural frequency of the atom, can be obtained stably.

Here, one of the causes of the performance decrease in the abovementioned atomic oscillator is a temperature shift in which the resonance frequency varies in response to a change in the temperature of the alkali metal atomic gas. That is to say, when a temperature change inside the oscillator occurs, the optical transition property of the atom varies, resulting in decrease of the stability of the oscillation frequency. Regarding such a problem, Patent Literature 1 describes that a temperature measurement element and a heater are provided outside an alkali metal cell. Accordingly, in Patent Literature 1, it is described that the temperature of the alkali metal cell is kept constant by heating the cell with the heater, using the temperature information of the alkali metal cell.

### CITATION LIST

### Patent Literature

[Patent Literature 1] JP 2017-011680 A

### SUMMARY OF INVENTION

### Technical Problem

However, in a case where the temperature of the alkali metal cell cannot be kept constant, a change in resonance frequency due to the temperature shift occurs, resulting in a problem of a decrease of the stability of the oscillation frequency. Moreover, in a case where not only the temperature of the alkali metal cell but also the environmental state of the atomic oscillator cannot be kept constant, there arises a problem that the stability of the oscillation frequency decreases. As a result, there is a problem that further increase of the stability of the oscillation frequency of the atomic oscillator cannot be achieved.

Accordingly, an object of the present disclosure is to provide an atomic oscillator that can solve the abovementioned problem that further increase of the stability of the oscillation frequency cannot be achieved.

### Solution to Problem

An atomic oscillator as an aspect of the present disclosure includes: a gas cell in which alkali metal atoms are encapsulated; a light generator that irradiates the gas cell with irradiation light having at least two different frequency components; a light detector that detects transmitted light transmitted through the gas cell; and a controller that determines a resonance frequency based on a light amount of the transmitted light of the gas cell and controls an oscillation frequency by an oscillator based on the determined resonance frequency. The atomic oscillator includes an agent that performs reinforcement learning so as to output an action controlling an environmental state of the atomic oscillator in accordance with the acquired environmental state, by using a reward corresponding to a difference between a preset reference frequency and the oscillation frequency.

Further, an atomic oscillator as an aspect of the present disclosure includes: a gas cell in which alkali metal atoms are encapsulated; a light generator that irradiates the gas cell with irradiation light having at least two different frequency components; a light detector that detects transmitted light transmitted through the gas cell; and a controller that determines a resonance frequency based on a light amount of the transmitted light of the gas cell and controls an oscillation frequency by an oscillator based on the determined resonance frequency. The atomic oscillator includes an agent that performs reinforcement learning so as to output an action controlling an environmental state of the atomic oscillator in accordance with the acquired environmental state, by using a reward corresponding to a difference between a preset reference frequency and the oscillation frequency. The agent outputs the action in accordance with the acquired environmental state of the atomic oscillator. The controller controls the environmental state of the atomic oscillator based on the action output by the agent.

Further, a control method as an aspect of the present disclosure is a control method by a control device in an atomic oscillator. The atomic oscillator includes: a gas cell in which alkali metal atoms are encapsulated; a light generator that irradiates the gas cell with irradiation light having at least two different frequency components; a light detector that detects transmitted light transmitted through the gas cell; and the control device that determines a resonance frequency based on a light amount of the transmitted light of the gas cell and controls an oscillation frequency by an oscillator based on the determined resonance frequency. In the control method, an agent included by the control device performs reinforcement learning so as to output an action controlling an environmental state of the atomic oscillator in accordance with the acquired environmental state, by using a reward corresponding to a difference between a preset reference frequency and the oscillation frequency.

Further, a control method as an aspect of the present disclosure is a control method by a control device in an atomic oscillator. The atomic oscillator includes: a gas cell in which alkali metal atoms are encapsulated; a light generator that irradiates the gas cell with irradiation light having at least two different frequency components; a light detector that detects transmitted light transmitted through the gas cell; and the control device that determines a resonance frequency based on a light amount of the transmitted light of the gas cell and controls an oscillation frequency by an oscillator based on the determined resonance frequency. In the control method, an agent, which is included by the control device and has performed reinforcement learning so as to output an action controlling an environmental state of the atomic oscillator in accordance with the acquired environmental state by using a reward corresponding to a difference between a preset reference frequency and the oscillation frequency, outputs the action in accordance with the acquired environmental state of the atomic oscillator, and the control device controls the environmental state of the atomic oscillator based on the action output from the agent.

Further, a control device as an aspect of the present disclosure is a control device in an atomic oscillator. The atomic oscillator includes: a gas cell in which alkali metal atoms are encapsulated; a light generator that irradiates the gas cell with irradiation light having at least two different frequency components; a light detector that detects transmitted light transmitted through the gas cell; and the control device that determines a resonance frequency based on a light amount of the transmitted light of the gas cell and controls an oscillation frequency by an oscillator based on the determined resonance frequency. The control device includes an agent that performs reinforcement learning so as to output an action controlling an environmental state of the atomic oscillator in accordance with the acquired environmental state, by using a reward corresponding to a difference between a preset reference frequency and the oscillation frequency.

Further, a control device as an aspect of the present disclosure is a control device in an atomic oscillator. The atomic oscillator includes: a gas cell in which alkali metal atoms are encapsulated; a light generator that irradiates the gas cell with irradiation light having at least two different frequency components; a light detector that detects transmitted light transmitted through the gas cell; and the control device that determines a resonance frequency based on a light amount of the transmitted light of the gas cell and controls an oscillation frequency by an oscillator based on the determined resonance frequency. The control device includes an agent having performed reinforcement learning so as to output an action controlling an environmental state of the atomic oscillator in accordance with the acquired environmental state by using a reward corresponding to a difference between a preset reference frequency and the oscillation frequency. The agent outputs the action in accordance with the environmental state of the atomic oscillator acquired by the agent, and the control device controls the environmental state of the atomic oscillator based on the output action.

Further, a computer program as an aspect of the present disclosure is a computer program including instructions for causing a control device in an atomic oscillator to execute processes. The atomic oscillator includes: a gas cell in which alkali metal atoms are encapsulated; a light generator that irradiates the gas cell with irradiation light having at least two different frequency components; a light detector that detects transmitted light transmitted through the gas cell; and the control device that determines a resonance frequency based on a light amount of the transmitted light of the gas cell and controls an oscillation frequency by an oscillator based on the determined resonance frequency. The computer program includes the instructions for causing the control device to execute the processes to control an agent included by the control device to perform reinforcement learning so as to output an action controlling an environmental state of the atomic oscillator in accordance with the acquired environmental state, by using a reward corresponding to a difference between a preset reference frequency and the oscillation frequency.

Further, a computer program as an aspect of the present disclosure is a computer program including instructions for causing a control device in an atomic oscillator to execute processes. The atomic oscillator includes: a gas cell in which alkali metal atoms are encapsulated; a light generator that irradiates the gas cell with irradiation light having at least two different frequency components; a light detector that detects transmitted light transmitted through the gas cell; and a control device that determines a resonance frequency based on a light amount of the transmitted light of the gas cell and controls an oscillation frequency by an oscillator based on the determined resonance frequency. The computer program includes the instructions for causing the control device to execute the processes to control an agent, which is included by the control device and has performed reinforcement learning so as to output an action controlling an environmental state of the atomic oscillator in accordance with the acquired environmental state by using a reward corresponding to a difference between a preset reference frequency and the oscillation frequency, to output the action in accordance with the acquired environmental state of the atomic oscillator, and control the environmental state of the atomic oscillator based on the output action.

### Advantageous Effects of Invention

With the configurations as described above, the present disclosure can provide an atomic oscillator that can achieve further increase of the stability of the oscillation frequency.

### BRIEF DESCRIPTION OF DRAWINGS

FIG. 1 is a block diagram showing an example of the configuration of an atomic oscillator in the present disclosure.

FIG. 2 is a diagram showing the overview of processing by the atomic oscillator in the present disclosure.

FIG. 3 is a flowchart showing an example of the processing operation of the atomic oscillator in the present disclosure.

FIG. 4 is a block diagram showing an example of the configuration of the atomic oscillator in the present disclosure.

FIG. 5 is a flowchart showing an example of the processing operation of the atomic oscillator in the present disclosure.

FIG. 6 is a block diagram showing an example of the configuration of an atomic oscillator in the present disclosure.

FIG. 7 is a flowchart showing an example of the processing operation of the atomic oscillator in the present disclosure.

FIG. 8 is a flowchart showing an example of the processing operation of the atomic oscillator in the present disclosure.

### EXAMPLE EMBODIMENTS

### First Example Embodiment

A first example embodiment of the present disclosure will be described with reference to the drawings. The drawings can be associated with any of the example embodiments.

### [Configuration]

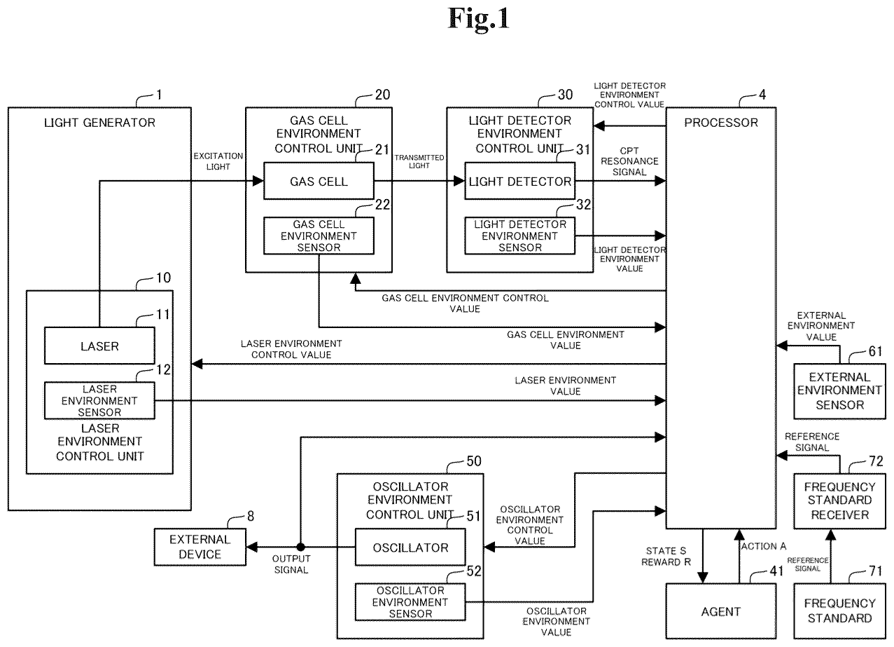

An atomic oscillator in the present disclosure includes, as shown in FIG. 1, a light generator 1 including a laser 11, a gas cell 21, a light detector 31, a processor 4, and an oscillator 51. The processor 4 is configured with an information processing device (control device (controller)) including an arithmetic logic unit and a memory unit, and each function unit to be described later of the processor 4 is implemented by execution of a program by the arithmetic logic unit.

The light generator 1 generates excitation light (irradiation light), which is light having at least two different frequencies, and irradiates the gas cell 21 with the light. For example, the light generator 1 generates excitation light of single wavelength of, for example, 894.5812 nm based on a set value specified by the processor 4 with the laser 11, and generates excitation light having two different frequency components by performing frequency modulation on the single-wavelength excitation light. Then, by irradiation of the gas cell 21 with the generated excitation light (irradiation light) by the light generator 1, light transmitted through the gas cell 21, that is, transmitted light reaches the light detector 31 and is detected, transformed into an electrical signal or the like, and sent to the processor 4.

At this time, the irradiation light applied by the light generator 1 to the gas cell 21 has at least two different frequency components. The irradiation light applied by the light generator 1 may have three or more different frequency components, but the difference frequency between two of the frequency components is substantially equal to the transition frequency between specific quantum states forming the CPT resonance of alkali metal atoms.

Here, the light generator 1 further includes a laser environment control unit 10. The laser environment control unit 10 includes a laser environment sensor 12 that measures a laser environment value (measurement value) representing the state of the laser 11, and also has a function of controlling the state of the laser 11. For example, an example of the state of the laser 11 includes the driving current of the laser 11 and the temperature of the laser 11, but any kind of state on the laser 11 may be used. As will be descried later, the laser environment control unit 10 notifies the processor 4 of the laser environment value measured by the laser environment sensor 12, and also controls the state of the laser 11 in accordance with a laser environment control value, which is a control command from the processor 4. As an example, the laser environment control unit 10 includes a temperature regulation device for the laser 11 such as a resistive heater and, using the temperature regulation device, controls a state, which is the temperature of the laser 11, in accordance with the laser environment control value. The state of the laser 11 is one of the environmental states of the atomic oscillator.

The gas cell 21 is configured with alkali metal atoms encapsulated in a container. The alkali metal atoms encapsulated in the gas cell 21 may be any of cesium atoms, rubidium atoms, sodium atoms, and potassium atoms, for example. A material forming the container of the gas cell 21 is preferably a transparent material such as glass having a large transmittance of the irradiation light generated by the light generator 1. In addition to the alkali metal atoms, a buffer gas that does not contribute to the absorption of the irradiation light may be enclosed in the gas cell 21 for the purpose of reducing the influence of collision between the container wall surface and the gaseous alkali metal atoms.

Further, the gas cell 21 is equipped with a temperature regulation device for the gas cell that regulates its own temperature. The gas cell temperature regulation device, which may be configured with, for example, a resistive heater, is configured with a device that has a function of heating or heating and cooling and that can regulate the temperature of the gas cell 21. Moreover, the gas cell 21 is equipped with a magnetic field application device (not shown). The magnetic field application device generates a magnetic field in a direction parallel to or antiparallel to the irradiation light at a predetermined position inside the gas cell 21. The magnetic field application device is configured with, for example, a coil placed to cover the gas cell 21 and, by regulation of the direction and magnitude of the current applied to the coil, control of the direction and intensity of a static magnetic field applied to the predetermined position inside the gas cell 21 can be achieved.

Here, the atomic oscillator further includes a gas cell environment control unit 20. The gas cell environment control unit 20 includes a gas cell environment sensor 22 that measures a gas cell environment value (measurement value) representing the state of the gas cell 21, and also has a function of controlling the state of the gas cell 21. For example, an example of the state of the gas cell 21 includes a magnetic field to the gas cell 21 and the temperature of the gas cell 21, but any kind of state on the gas cell 21 may be used. As will be described later, the gas cell environment control unit 20 notifies the processor 4 of the gas cell environment value measured by the gas cell environment sensor 22, and also controls the state of the gas cell 21 in accordance with a gas cell environment control value, which is a control command from the processor 4. The state of the gas cell 21 is one of the environmental states of the atomic oscillator.

The light detector 31 has a device that detects the transmitted light, which is light transmitted through the gas cell 21. The light detector 31 is implemented by using, for example, an optical diode, but may be implemented by any light detection means. The information of the light detected by the light detector 31 is transformed into an electrical signal or the like and input to the processor 4.

Here, the atomic oscillator further includes a light detector environment control unit 30. The light detector environment control unit 30 includes a light detector environment sensor 32 that measures a light detector environment value (measurement value) representing the state of the light detector 31, and also has a function of controlling the state of the light detector 31. For example, an example of the state of the light detector 31 includes the temperature of the light detector 31, but any kind of state on the light detector 31 may be used. As will be described later, the light detector environment control unit 30 notifies the processor 4 of the light detector environment value measured by the light detector environment sensor 32, and also controls the state of the light detector 31 in accordance with a light detector environment control value, which is a control command from the processor 4. The state of the light detector 31 is one of the environmental states of the atomic oscillator.

The processor 4 determines the resonance frequency from the amount of transmitted light input from the light detector 31, and controls then oscillation frequency by the oscillator 51 based on the determined resonance frequency. To be specific, the processor 4 sweeps the difference frequency of the irradiation light, determines the resonance frequency from a transmitted light spectrum and, after once determining the resonance frequency, regulates the control voltage of the oscillator 51 in such a manner that the error signal of the transmitted light spectrum obtained by lock-in detection is at a predetermined signal level. Here, the oscillator 51 is configured with a voltage control crystal oscillator (VCXO) that oscillates at about 10 MHz, and the oscillator generates an oscillation signal in accordance with the control voltage output and applied by the processor 4, and outputs the oscillation signal to an external device 8 as the oscillation frequency, which is an external output by the atomic oscillator. Consequently, the oscillation frequency is stabilized to 10 MHz unless the resonance frequency changes. Moreover, the difference frequency of the irradiation light is generated by conversion of the oscillation signal of the VCXO into a signal of several GHz by a multiplier, and input to the light generator 1.

Here, the atomic oscillator further includes an oscillator environment control unit 50. The oscillator environment control unit 50 includes an oscillator environment sensor 52 that measures an oscillator environment value (measurement value) representing the state of the oscillator 51, and also has a function of controlling the state of the oscillator 51. For example, an example of the state of the oscillator 51 includes the control voltage of the oscillator 51 and the temperature of the oscillator 51, but any kind of state on the oscillator 51 may be used. As will be described later, the oscillator environment control unit 50 notifies the processor 4 of the oscillator environment value measured by the oscillator environment sensor 52, and also controls the state of the oscillator 51 in accordance with an oscillator environment control value, which is a control command from the processor 4. The state of the oscillator 51 is one of the environmental states of the atomic oscillator.

In addition, the atomic oscillator further includes an external environment sensor 61. The external environment sensor 61 measures an external environment value (measurement value) representing the state of the atomic oscillator or the state of the surroundings of the atomic oscillator. An example of the state of the atomic oscillator includes the acceleration of the atomic oscillator itself and the magnetic field and temperature of the surroundings (exterior) of the atomic oscillator, but any kind of state on the atomic oscillator may be used. The external environment sensor 61 notifies the processor 4 of the measured external environment value as will be described later. The state of the atomic oscillator is one of the environmental states of the atomic oscillator.

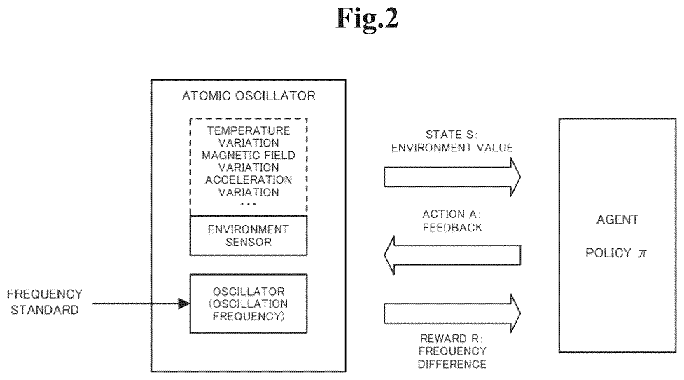

Further, the atomic oscillator includes an agent 41 that performs reinforcement learning so as to output actions, which are control commands, namely, the environment control values to control the states of the atomic oscillator itself and the respective components, in accordance with the respective measured environment values representing the states of the atomic oscillator itself and the respective components described above. The agent 41 is constructed by execution of a program by the arithmetic logic unit, and is provided inside a control device including the processor 4 described above, for example. Then, the agent 41 performs machine learning in cooperation with the processor 4, specifically, performs reinforcement learning as described below. FIG. 2 shows the overview of processing when the agent 41 performs reinforcement learning.

First, the processor 4 acquires the environmental values representing the states of the atomic oscillator measured by the respective sensors and the like described above. As an example, the processor 4 acquires the measured environment values (measurement values) such as the driving current of the laser 11 as the laser environment value from the laser environment sensor 12, the temperature of the gas cell 21 as the gas cell environment value from the gas cell environment sensor 22, the temperature of the light detector 32 as the light detector environment value from the light detector environment sensor 32, the control voltage of the oscillator 51 as the oscillator environment value from the oscillator environment sensor 52, and the external temperature and the external magnetic field as the external environment values from the external environment sensor 61. Then, the processor 4 passes each of the environment values having been acquired as a state S of the atomic oscillator to the agent 41.

The agent 41 having acquired the state S of the atomic oscillator outputs an environment control value that is an action A corresponding to the environment value that is the state S, in accordance with a policy 7c that is a function that can be optimized by reinforcement learning. At this time, the policy 7t of the agent 41 outputs an action A, which is an environment control value changing each of the measured environment values, for example. As an example, the policy outputs environmental control values including change rates such as the driving voltage of the laser 11 by +1%, the temperature control voltage of the gas cell 21 by +2%, and the control voltage of the oscillator 51 by −1%, or outputs concrete voltage values corresponding to the measured environment values.

The processor 4 having received the output of the environment control values from the agent 41 controls in such a manner that the components of the atomic oscillator are in the states of the respective environment control values. That is to say, the processor 4 controls the states of voltage values applied to the laser 11, the gas cell 21, the light detector 31, the oscillator 51 and so forth of the respective environment control units 10 and so forth in accordance with the respective environment control values. Then, the processor 4 acquires an oscillation frequency, which is an output signal by the atomic oscillator in the state controlled in accordance with the respective environment control values. At this time, the processor 4 acquires a reference frequency output from a frequency standard 71 via a frequency standard receiver 72. The reference frequency is a target value of the oscillation frequency by the atomic oscillator, which is a value of 10 MHz, for example. The frequency standard receiver 72 may receive the reference frequency via wireless communication, or may receive the reference frequency using the Global Positioning System (GPS), or may receive the reference frequency by any method and pass the reference frequency to the processor 4.

Then, the processor 4 calculates the difference between the oscillation frequency and the reference frequency, calculates a reward R based on the difference, and passes the reward R to the agent 41 for use in reinforcement learning. At this time, the processor 4 sets the reward R in such a manner that the value is larger as the absolute value (|Δf|) of the difference between the oscillation frequency and the reference frequency is smaller. Furthermore, the processor 4 also sets the reward R according to the lapse of time t of reinforcement learning performed by the agent 41 as will be described later. For example, the processor 4 sets the reward R in such a manner that the value is smaller as the time t of reinforcement learning elapses. As an example, the processor 4 calculates the reward R by Formula 1 below with γ(<1) as a discount factor.

$$R = \{ 1 / ( \vert Δ f \vert + 1 ) \} \times {γ}^{t} \qquad [ Formula 1 ]$$

The agent 41 performs reinforcement learning of the policy a that outputs the action A from the state S that is the acquired environment value, by using the reward R received from the processor 4. For example, the agent 41 performs Q learning to update an action value function Q shown by Formula 2 below, and updates the policy π. At this time, the agent 41 performs reinforcement learning by giving a plurality of actions A for one state S. Here, α denotes a learning rate, greater than 0 and less than 1.

$$Q ( {S}_{t} , {A}_{t} ) ← ( 1 - α ) Q ( {S}_{t} , {A}_{t} ) + α [ {R}_{t + 1} + γ {max}_{a} Q ( {S}_{t + 1} , a ) ] \qquad [ Formula 2 ]$$

In the abovementioned reinforcement learning, the agent 41 may perform Deep Q-Learning (DQN) and update the policy π. In addition, the agent 41 may update the policy a using the reward as described above by still another method of machine learning, such as neural network.

The agent 41 is configured to output an optimal action A, namely, an environment control value in accordance with the state S of the atomic oscillator by performing reinforcement learning as described above. For example, the manufacture of the atomic oscillator may cause the agent 41 to perform reinforcement learning described above before product shipment. Alternatively, even after product shipment by the manufacture of the atomic oscillator, the agent 41 may perform reinforcement learning as described above at a preset timing or any timing and update so that an optimal action A is always output. In this case, the atomic oscillator is configured to acquire the reference frequency by, for example, wireless communication or GPS.

### [Operation]

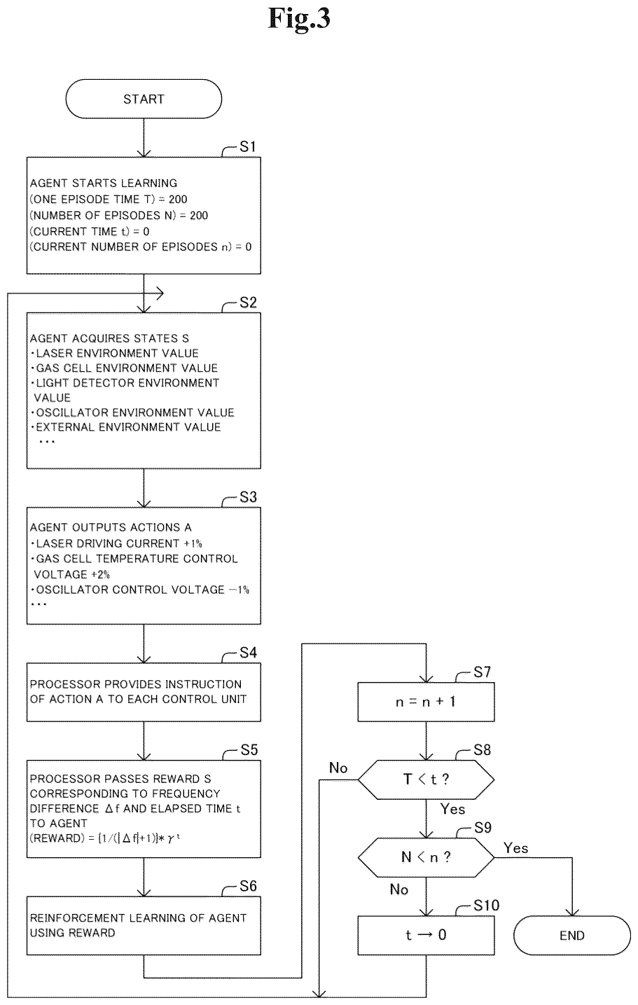

Next, processing operation at the time of reinforcement learning of the agent 41 by the atomic oscillator described above will be described. First, the processor 4 sets various parameters at the start of reinforcement learning of the agent 41. For example, the processor sets one episode time T=200, which is a period from the start to the end of an action to an environment given for reinforcement learning, number of episodes N=200, current time t=0, and current number of episodes n=0 (step S1 of FIG. 3).

Subsequently, the processor 4 acquires measured environmental values, which are states S of the atomic oscillator, and passes them to the agent 41 (step S2 of FIG. 3). For example, the processor 4 acquires measured environment values (measurement values) such as the driving current of the laser 11, which is a laser environment value, the temperature of the gas cell 21, which is a gas cell environment value, the temperature of the light detector 32, which is a light detector environment value, the control voltage of the oscillator 51, which is an oscillator environment value, and the external temperature and the external magnetic field, which are external environment values, and passes them to the agent 41.

Subsequently, the agent 41 outputs environment control values, which are actions A corresponding to the respective environment values that are the received states S, in accordance with a policy a, which is a function that can be optimized by reinforcement learning, and passes them to the processor 4 (step S3 of FIG. 3). For example, the agent 41 outputs environmental control values including change rates such as the driving voltage of the laser 11 by +1%, the temperature control voltage of the gas cell 21 by +2%, and the control voltage of the oscillator 51 by −1%, as an example of the actions A.

Subsequently, the processor 4 controls in such a manner that the components of the atomic oscillator are in the states of the environment control values corresponding to the output actions A (step S4 of FIG. 3). That is to say, the processor 4 causes the respective environment control units 10 and so forth to control the states of voltage values applied to the laser 11, the gas cell 21, the light detector 31, the oscillator 51 and so forth in accordance with the respective environment control values corresponding to the output actions A.

Subsequently, the processor 4 acquires an oscillation frequency that is an output signal by the atomic oscillator in the state controlled in accordance with the respective environment control values, calculates a reward R corresponding to a difference Δf between the oscillation frequency and the reference frequency and an elapsed time t of learning, and passes it to the agent 41. At this time, for example, by calculating the reward R using Formula 1 described above, the processor 4 calculates the reward R in such a manner that the value is larger as the absolute value (|Δf|) of the difference between the oscillation frequency and the reference frequency is smaller and the value is smaller as the time t of reinforcement learning passes.

Subsequently, the agent 41 performs reinforcement learning of the policy a that outputs the action A from the state S that is the acquired environment value and updates the policy a, by using the reward R received from the processor 4 (step S6 of FIG. 3). Then, the processor 4 and the agent 41 perform reinforcement learning by repeatedly executing the above processing until the respective parameters satisfy the set conditions as described above (steps S7 to S10). Consequently, the policy 7t of the agent 41 is configured to output an environment control value that is the optimal action A in accordance with the state S of the atomic oscillator.

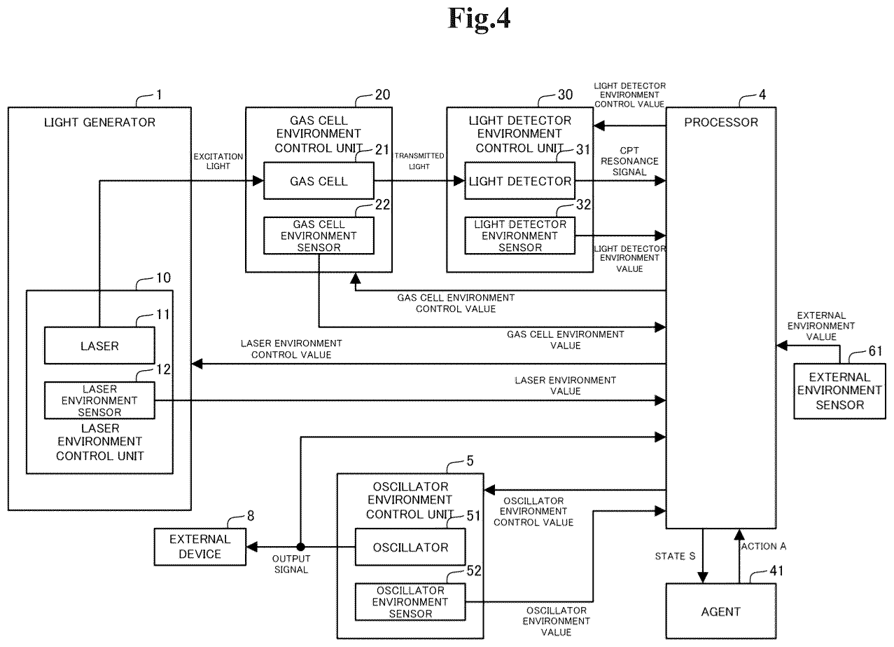

Next, processing operation at the use of the atomic oscillator where the agent 41 of the atomic oscillator has already done reinforcement learning as described above will be described. In this case, since the agent 41 has already done reinforcement learning, the atomic oscillator does not need to be equipped with the configuration necessary for reinforcement learning described above, as shown in FIG. 4. For example, the atomic oscillator shipped by the manufacture may be configured as shown in FIG. 4. However, even if the agent 41 has already done reinforcement learning, the atomic oscillator may be configured as shown in FIG. 1, and the agent 41 may be updated by reinforcement learning of the agent 41 after the shipment of the atomic oscillator by the manufacture.

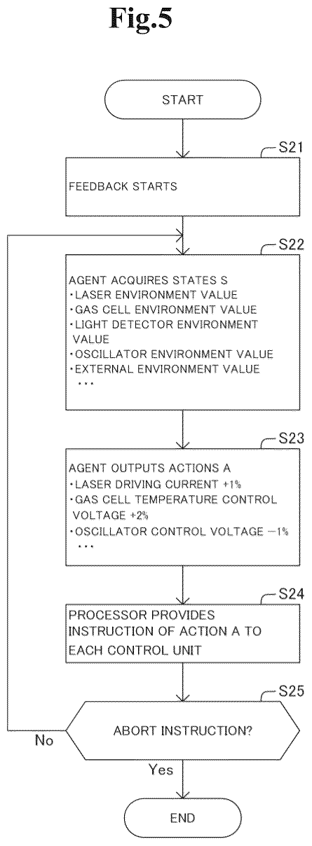

First, when the use of the atomic oscillator starts (step S21 of FIG. 5), the processor 4 acquires measured environmental values, which are states S of the atomic oscillator, and passes them to the agent 41 (step S22 of FIG. 5). For example, the processor 4 acquires measured environment values (measurement values) such as the driving current of the laser 11, which is a laser environment value, the temperature of the gas cell 21, which is a gas cell environment value, the temperature of the light detector 32, which is a light detector environment value, the control voltage of the oscillator 51, which is an oscillator environment value, and the external temperature and the external magnetic field, which are external environment values, and passes them to the agent 41.

Subsequently, the agent 41 outputs environment control values, which are actions A corresponding to the environment values that are the received states S, in accordance with a policy a, which is a function optimized by reinforcement learning, and passes them to the processor 4 (step S23 of FIG. 5). For example, the agent 41 outputs environmental control values including change rates such as the driving voltage of the laser 11 by +1%, the temperature control voltage of the gas cell 21 by +2%, and the control voltage of the oscillator 51 by −1%, as an example of the actions A.

Subsequently, the processor 4 controls in such a manner that the components of the atomic oscillator are in the states of the environment control values corresponding to the output actions A (step S24 of FIG. 5). That is to say, the processor 4 causes the respective environment control units 10 and so forth to control the states of voltage values applied to the laser 11, the gas cell 21, the light detector 31, the oscillator 51 and so forth in accordance with the respective environment control values corresponding to the output actions A. Then, the abovementioned control is continued until an abort instruction is input (step S25 of FIG. 5).

Accordingly, the atomic oscillator of the present disclosure performs reinforcement learning using a reward corresponding to the difference between the oscillation frequency and the reference frequency so that the agent 41 outputs the optimal control action corresponding to the current state of the atomic oscillator. Consequently, it is possible to achieve increase of the frequency stability of the atomic oscillator by controlling the atomic oscillator based on the action output from the agent 41 having already done reinforcement learning.

### Second Example Embodiment

Next, a second example embodiment of the present disclosure will be described with reference to the drawings. In this example embodiment, the overview of the configurations of the atomic oscillator and so forth described in the above example embodiment is shown. The drawings may be associated with any of the example embodiments.

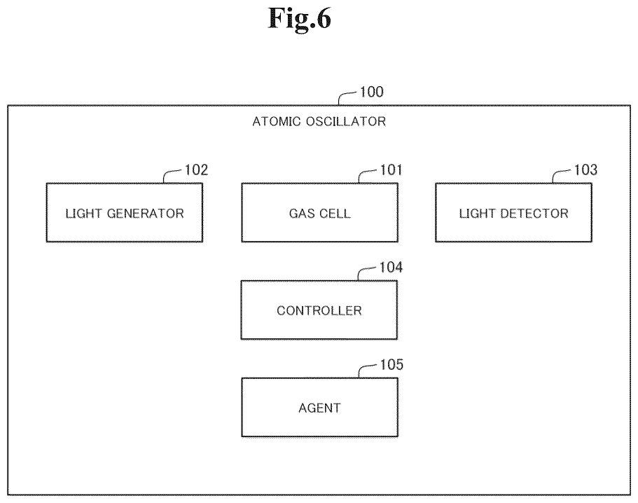

An atomic oscillator 100 in the present disclosure includes, as shown in FIG. 6, a gas cell 101 in which alkali metal atoms are encapsulated, a light generator 102 that irradiates the gas cell with irradiation light having at least two different frequency components, a light detector 103 that detects transmitted light transmitted through the gas cell, a controller 104 that determines a resonance frequency based on the light amount of the transmitted light of the gas cell and controls an oscillation frequency by an oscillator based on the determined resonance frequency, and an agent 105 that performs reinforcement learning so as to output an action controlling the state of an environment in accordance with the state of the environment of the atomic oscillator having been acquired, by using a reward corresponding to the difference between a preset reference frequency and the oscillation frequency.

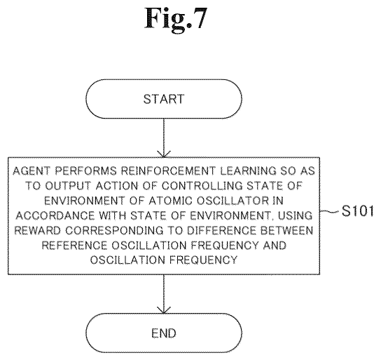

Then, in the atomic oscillator configured as described above, the agent 105 performs reinforcement learning so as to output an action controlling the state of the environment according to the state of the environment of the atomic oscillator having been acquired, by using a reward corresponding to the difference between a preset reference frequency and the oscillation frequency (step S101 of FIG. 7).

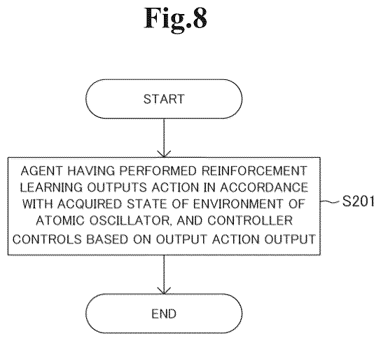

Further, in the atomic oscillator configured as described above, the agent 105 having performed reinforcement learning outputs an action in accordance with the state of the environment of the atomic oscillator having been acquired, and the controller 104 controls the state of the environment of the atomic oscillator based on the action output from the agent (step S201 of FIG. 8).

As described above, in the present disclosure, the agent performs reinforcement learning by using a reward corresponding to the difference between the oscillation frequency and the reference frequency so as to output the optimal control action corresponding to the current state of the atomic oscillator. Therefore, it is possible to achieve increase of the frequency stability of the atomic oscillator by controlling the atomic oscillator based on the action output from the agent having performed reinforcement learning.

Although the present disclosure has been described above with reference to example embodiments, the present disclosure is not limited to the example embodiments described above. The configuration and details of the present disclosure can be changed in a variety of ways that those skilled in the art can understand within the scope of the present disclosure. Then, each of the example embodiments described above can be combined with the other example embodiment as necessary.

### <Supplementary Notes>

The whole or part of the example embodiments disclosed above can be described as the following supplementary notes. Below, the overview of the configurations of an atomic oscillator and so forth in the present disclosure will be described. However, the present disclosure is not limited to the configurations described in the following supplementary notes.

All or some of configurations described in Supplementary Notes 2 to 8.2 dependent on Supplementary Note 1 described above and the functions by such configurations may be dependent on other Supplementary Notes 9 to 15 by the same dependence as Supplementary Notes 2 to 8.2. Furthermore, not limited to Supplementary Notes 1, 9 to 15, all of some of configurations described as supplementary notes and functions by such configurations may also be dependent on similar hardware, software, various recording means for recording software, or system within the scope of the example embodiments described above.

### (Supplementary Note 1)

An atomic oscillator including:
a gas cell in which alkali metal atoms are encapsulated;
a light generator that irradiates the gas cell with irradiation light having at least two different frequency components;
a light detector that detects transmitted light transmitted through the gas cell; and
a controller that determines a resonance frequency based on a light amount of the transmitted light of the gas cell and controls an oscillation frequency by an oscillator based on the determined resonance frequency,
the atomic oscillator comprising
an agent that performs reinforcement learning so as to output an action controlling an environmental state of the atomic oscillator in accordance with the acquired environmental state, by using a reward corresponding to a difference between a preset reference frequency and the oscillation frequency.

### (Supplementary Note 2)

The atomic oscillator according to supplementary note 1, wherein:
the controller sets the reward such that a value is larger as an absolute value of the difference between the oscillation frequency and the reference frequency is smaller; and
the agent performs the reinforcement learning by using the reward.

### (Supplementary Note 3)

The atomic oscillator according to supplementary note 1, wherein:
the controller sets the reward corresponding to a lapse of time of the reinforcement learning; and
the agent performs the reinforcement learning by using the reward.

### (Supplementary Note 4)

The atomic oscillator according to supplementary note 3, wherein
the controller sets the reward such that a value is smaller as the time of the reinforcement learning elapses.

### (Supplementary Note 5)

The atomic oscillator according to supplementary note 1, wherein:
the controller sets the reward corresponding to the difference between the oscillation frequency and the reference frequency at a time of controlling the environmental state of the atomic oscillator based on the action output by the agent; and the agent performs the reinforcement learning by using the reward.

### (Supplementary Note 6)

The atomic oscillator according to supplementary note 1, wherein:
the agent outputs the action in accordance with the acquired environmental state of the atomic oscillator; and
the controller controls the environmental state of the atomic oscillator based on the action output by the agent.

### (Supplementary Note 7)

The atomic oscillator according to supplementary note 1, wherein
the environmental state acquired by the agent is at least one of measurement values measured from the gas cell, the light generator, the light detector, and the oscillator.

### (Supplementary Note 8)

The atomic oscillator according to supplementary note 1, wherein
the action output by the agent is a control value controlling at least one of states of the gas cell, the light generator, the light detector, and the oscillator.

### (Supplementary Note 8.1)

The atomic oscillator according to supplementary note 1, wherein
the agent performs Q learning as the reinforcement learning.

### (Supplementary Note 8.2)

The atomic oscillator according to supplementary note 1, comprising
a receiver that receives the reference frequency from outside.

### (Supplementary Note 9)

An atomic oscillator including:
a gas cell in which alkali metal atoms are encapsulated;
a light generator that irradiates the gas cell with irradiation light having at least two different frequency components;
a light detector that detects transmitted light transmitted through the gas cell; and
a controller that determines a resonance frequency based on a light amount of the transmitted light of the gas cell and controls an oscillation frequency by an oscillator based on the determined resonance frequency,
the atomic oscillator comprising
an agent that performs reinforcement learning so as to output an action controlling an environmental state of the atomic oscillator in accordance with the acquired environmental state, by using a reward corresponding to a difference between a preset reference frequency and the oscillation frequency, wherein:
the agent outputs the action in accordance with the acquired environmental state of the atomic oscillator; and
the controller controls the environmental state of the atomic oscillator based on the action output by the agent.

### (Supplementary Note 10)

A control method by a control device in an atomic oscillator, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the control method, wherein
an agent included by the control device performs reinforcement learning so as to output an action controlling an environmental state of the atomic oscillator in accordance with the acquired environmental state, by using a reward corresponding to a difference between a preset reference frequency and the oscillation frequency.

### (Supplementary Note 11)

A control method by a control device in an atomic oscillator, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the control method, wherein
an agent, which is included by the control device and has performed reinforcement learning so as to output an action controlling an environmental state of the atomic oscillator in accordance with the acquired environmental state by using a reward corresponding to a difference between a preset reference frequency and the oscillation frequency, outputs the action in accordance with the acquired environmental state of the atomic oscillator, and the control device controls the environmental state of the atomic oscillator based on the action output from the agent.

### (Supplementary Note 12)

A control device in an atomic oscillator, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the control device comprising
an agent that performs reinforcement learning so as to output an action controlling an environmental state of the atomic oscillator in accordance with the acquired environmental state, by using a reward corresponding to a difference between a preset reference frequency and the oscillation frequency.

### (Supplementary Note 13)

A control device in an atomic oscillator, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the control device comprising
an agent having performed reinforcement learning so as to output an action controlling an environmental state of the atomic oscillator in accordance with the acquired environmental state by using a reward corresponding to a difference between a preset reference frequency and the oscillation frequency, wherein
the agent outputs the action in accordance with the acquired environmental state of the atomic oscillator, and the control device controls the environmental state of the atomic oscillator based on the output action.

### (Supplementary Note 14)

A computer program comprising instructions for causing a control device in an atomic oscillator to execute processes, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the computer program comprising the instructions for causing the control device to execute the processes to
control an agent included by the control device to perform reinforcement learning so as to output an action controlling an environmental state of the atomic oscillator in accordance with the acquired environmental state, by using a reward corresponding to a difference between a preset reference frequency and the oscillation frequency.

### (Supplementary Note 15)

A computer program comprising instructions for causing a control device in an atomic oscillator to execute processes, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the computer program comprising the instructions for causing the control device to execute the processes to
control an agent, which is included by the control device and has performed reinforcement learning so as to output an action controlling an environmental state of the atomic oscillator in accordance with the acquired environmental state by using a reward corresponding to a difference between a preset reference frequency and the oscillation frequency, to output the action in accordance with the acquired environmental state of the atomic oscillator, and control the environmental state of the atomic oscillator based on the output action.

### REFERENCE SIGNS LIST

1 light generator
10 laser environment control unit
11 laser
12 laser environment sensor
20 gas cell environment control unit
21 gas cell
22 gas cell environment sensor
30 light detector environment control unit
31 light detector
32 light detector environment sensor
4 processor
41 agent
50 oscillator environment control unit
51 oscillator
52 oscillator environment sensor
61 external environment sensor
71 frequency standard
72 frequency standard receiver
8 external device
100 atomic oscillator
101 gas cell
102 light generator
103 light detector
104 controller
105 agent

1. An atomic oscillator including:
a gas cell in which alkali metal atoms are encapsulated;
a light generator that irradiates the gas cell with irradiation light having at least two different frequency components;
a light detector that detects transmitted light transmitted through the gas cell; and
a controller that determines a resonance frequency based on a light amount of the transmitted light of the gas cell and controls an oscillation frequency by an oscillator based on the determined resonance frequency,
the atomic oscillator comprising
an agent that performs reinforcement learning so as to output an action controlling an environmental state of the atomic oscillator in accordance with the acquired environmental state, by using a reward corresponding to a difference between a preset reference frequency and the oscillation frequency.

2. The atomic oscillator according to claim 1, wherein:
the controller sets the reward in such a manner that a value is larger as an absolute value of the difference between the oscillation frequency and the reference frequency is smaller; and
the agent performs the reinforcement learning by using the reward.

3. The atomic oscillator according to claim 1, wherein:
the controller sets the reward corresponding to a lapse of time of the reinforcement learning; and
the agent performs the reinforcement learning by using the reward.

4. The atomic oscillator according to claim 3, wherein
the controller sets the reward in such a manner that a value is smaller as the time of the reinforcement learning elapses.

5. The atomic oscillator according to claim 1, wherein:
the controller sets the reward corresponding to the difference between the oscillation frequency and the reference frequency at a time of controlling the environmental state of the atomic oscillator based on the action output by the agent; and
the agent performs the reinforcement learning by using the reward.

6. The atomic oscillator according to claim 1, wherein:
the agent outputs the action in accordance with the acquired environmental state of the atomic oscillator; and
the controller controls the environmental state of the atomic oscillator based on the action output by the agent.

7. The atomic oscillator according to claim 1, wherein
the environmental state acquired by the agent is at least one of measurement values measured from the gas cell, the light generator, the light detector, and the oscillator.

8. The atomic oscillator according to claim 1, wherein
the action output by the agent is a control value controlling at least one of states of the gas cell, the light generator, the light detector, and the oscillator.

9. The atomic oscillator according to claim 1, wherein
the agent performs Q learning as the reinforcement learning.

10. The atomic oscillator according to claim 1, comprising
a receiver that receives the reference frequency from outside.

11. An atomic oscillator including:
a gas cell in which alkali metal atoms are encapsulated;
a light generator that irradiates the gas cell with irradiation light having at least two different frequency components;
a light detector that detects transmitted light transmitted through the gas cell; and
a controller that determines a resonance frequency based on a light amount of the transmitted light of the gas cell and controls an oscillation frequency by an oscillator based on the determined resonance frequency,
the atomic oscillator comprising
an agent that performs reinforcement learning so as to output an action controlling an environmental state of the atomic oscillator in accordance with the acquired environmental state, by using a reward corresponding to a difference between a preset reference frequency and the oscillation frequency, wherein:
the agent outputs the action in accordance with the acquired environmental state of the atomic oscillator; and
the controller controls the environmental state of the atomic oscillator based on the action output by the agent.

12. A control method by a control device in an atomic oscillator, the atomic oscillator including:
a gas cell in which alkali metal atoms are encapsulated;
a light generator that irradiates the gas cell with irradiation light having at least two different frequency components;
a light detector that detects transmitted light transmitted through the gas cell; and
the control device that determines a resonance frequency based on a light amount of the transmitted light of the gas cell and controls an oscillation frequency by an oscillator based on the determined resonance frequency,
the control method, wherein
an agent included by the control device performs reinforcement learning so as to output an action controlling an environmental state of the atomic oscillator in accordance with the acquired environmental state, by using a reward corresponding to a difference between a preset reference frequency and the oscillation frequency.

13. The control method according to claim 12, wherein:
the control device sets the reward in such a manner that a value is larger as an absolute value of the difference between the oscillation frequency and the reference frequency is smaller; and
the agent performs the reinforcement learning by using the reward.

14. The control method according to claim 12, wherein:
the control device sets the reward corresponding to a lapse of time of the reinforcement learning; and
the agent performs the reinforcement learning by using the reward.

15. The control method according to claim 14, wherein
the control device sets the reward in such a manner that a value is smaller as the time of the reinforcement learning elapses.

16. The control method according to claim 12, wherein:
the control device sets the reward corresponding to the difference between the oscillation frequency and the reference frequency at a time of controlling the environmental state of the atomic oscillator based on the action output by the agent; and
the agent performs the reinforcement learning by using the reward.

17. The control method according to claim 12, wherein:
the agent outputs the action in accordance with the acquired environmental state of the atomic oscillator; and
the control device controls the environmental state of the atomic oscillator based on the action output by the agent.

18. The control method according to claim 12, wherein
the environmental state acquired by the agent is at least one of measurement values measured from the gas cell, the light generator, the light detector, and the oscillator.

19. The control method according to claim 12, wherein
the action output by the agent is a control value controlling at least one of states of the gas cell, the light generator, the light detector, and the oscillator.

20. The control method according to claim 12, wherein
the agent performs Q learning as the reinforcement learning.
